(19) United States
(12) Patent Application Publication
(10) Pub. No.: US 2004/0196057 A1
(43) Pub. Date: Oct. 7, 2004

(54) Socket or adapter device for semiconductor devices, method for testing semiconductor devices, and system comprising at least one socket or adapter device

(75) Inventor: Holger Hoppe, Mering (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 10/753,082

(22) Filed: Jan. 8, 2004

(30) Foreign Application Priority Data
Jan. 9, 2003 (DE) 103 00 531.5

(51) Int. Cl. G01R 31/02

(52) U.S. Cl. 324/754

(57) ABSTRACT

The invention relates to a method for testing semiconductor devices, to a system including at least one socket or adapter device, and to a socket or adapter device, in particular for semiconductor devices, having at least one connection pin which is designed such that it is adapted to be introduced into a corresponding contact device of a device to which the socket or adapter device is to be connected, wherein the connection pin is designed such that a clamping connection is provided between the contact device and the connection pin when the connection pin is introduced into the contact device.

### CLAIM FOR PRIORITY

This application claims the benefit of priority to German Application No. 103 00 531.5, filed in the German language on Jan. 9, 2003, the contents of which are hereby incorporated by reference.

### TECHNICAL FIELD OF THE INVENTION

The invention relates to a socket or adapter device, in particular for semiconductor devices, a method for testing semiconductor devices, and a system comprising at least one socket or adapter device.

### BACKGROUND OF THE INVENTION

Semiconductor devices, e.g. appropriate, integrated (analog or digital) computing circuits, semiconductor memory devices such as functional memory devices (PLAs, PALs, etc.) and table memory devices (e.g. ROMs or RAMs, in particular SRAMs and DRAMs), etc. are subject to comprehensive tests in the course of the manufacturing process.

For the common manufacturing of a plurality of (in general identical) semiconductor devices, a so-called wafer (i.e. a thin disc consisting of monocrystalline silicon) is used.

The wafer is processed appropriately (e.g. subject to a plurality of coating, exposure, etching, diffusion and implantation process steps, etc.), and subsequently e.g. sawn apart (or e.g. scratched and broken), so that the individual devices are then available.

After the sawing apart of the wafer, the devices—which are then available individually—are loaded each individually into special housings or packages, respectively (e.g. so-called TSOP or FBGA housings, etc.), and are then—for performing various testing methods—transported further to an appropriate testing station (or successively to a plurality of different testing stations).

At the respective testing station, individual devices available in the above-mentioned housings each are loaded into a corresponding adapter or socket, respectively, that is connected with a corresponding testing apparatus, and subsequently the device available in the respective housing is tested.

The testing station may, for instance, be a so-called burn-in testing station where a so-called burn-in test is performed, i.e. a test under extreme conditions (e.g. high temperature, for instance over 80° C. or 100° C., increased operating voltage, etc.).

At the burn-in testing station, a plurality of (e.g. special burn-in) sockets or adapters, respectively, is conventionally provided, into each of which a device to be tested is loaded.

The burn-in sockets (e.g. corresponding FBGA burn-in sockets) each are connected by means of appropriate soldering connections to a corresponding test circuit board which is connected with a corresponding testing apparatus.

This way, a plurality of—e.g. more than 100 or more than 200—devices can be tested simultaneously at the burn-in testing station by one and the same testing apparatus.

Burn-in sockets or adapters, respectively, are relatively expensive and relatively susceptible to faults (caused, for instance, by pollution, tin-lead-migration from the package soldering ball to the socket contact, etc).

When a faulty socket or adapter is to be exchanged on the test circuit board and to be replaced by a faultless socket or adapter, the corresponding faulty socket or adapter conventionally will have to be removed from the test circuit board by means of an appropriate unsoldering process, and then the corresponding replacement socket or replacement adapter will have to be soldered into the corresponding test circuit board.

This procedure is relatively time-consuming.

Moreover, there is the risk that the circuit board will be overheated and damaged or destroyed, respectively, in the course of the socket or adapter exchange procedure.

This is because the individual socket or adapter pins soldered into corresponding test circuit board bores at the respective socket or adapter only have a relatively small distance to one another (the distance between two socket or adapter pins positioned side by side may, for instance, be smaller than 1 mm, e.g. merely 0.8 mm).

The bores provided in the test circuit board and incorporating the pins therefore have relatively small dimensions (e.g. a diameter smaller than 0.5 mm, e.g. merely 0.3 mm).

For this reason, the solder remaining in the respective circuit board bores after the unsoldering of a faulty socket or adapter cannot be removed (or is difficult to remove, respectively).

Therefore, the circuit board has to be (locally) heated when the corresponding replacement socket is soldered in, so that the solder remaining in the respective bores can fuse, and the respective pins can then be introduced into the respective bores and be soldered therewith. During this procedure, overheating and damage or destruction, respectively, of the corresponding circuit board may occur.

### SUMMARY OF THE INVENTION

The invention provides a novel socket or adapter device, in particular for semiconductor devices, a novel method for testing semiconductor devices, and a novel system, in particular a semiconductor device testing system, comprising at least one socket or adapter device.

In accordance with one embodiment of the invention, a socket or adapter device, in particular for semiconductor devices, is provided, comprising at least one connection pin which is designed such that is adapted to be introduced into a corresponding contact device of a device, in particular a circuit board, to which the socket or adapter device is to be connected, wherein the connection pin is designed such that a clamping connection is provided between the contact device and the connection pin when the connection pin is introduced into the contact device.

Advantageously, at least one section of the connection pin has a curved shape, in particular substantially the shape of a wave.

Preferably, the connection between the connection pin and the contact device (and advantageously in addition also the corresponding connections between further connection pins and further contact means) is/are performed without soldering.

When, later on, a faulty socket device is to be dismounted from the device, in particular the circuit board, and to be exchanged by a faultless socket device, no unsoldering of the connection pins is necessary.

Overheating of the corresponding circuit board can be avoided thereby.

Moreover, the exchange of the socket device requires relatively little time.

### BRIEF DESCRIPTION OF THE DRAWINGS

In the following, the invention will be explained in detail with respect to the drawings, in which:

FIG. 1 shows stations passed through by corresponding semiconductor devices during the manufacturing of semiconductor devices.

FIG. 2 shows a side view of a socket used with the burn-in testing system illustrated in FIG. 1.

FIG. 3 shows a bottom view of the socket illustrated in FIG. 2.

FIG. 4 shows a side view of a section of the circuit board illustrated in FIG. 1, and of a section of the socket illustrated in FIGS. 1, 2, and 3, with a connection pin inserted into a circuit board contact.

FIG. 5 shows a side view of the connection pins illustrated in FIGS. 2, 3, and 4.

### DETAILED DESCRIPTION OF THE INVENTION

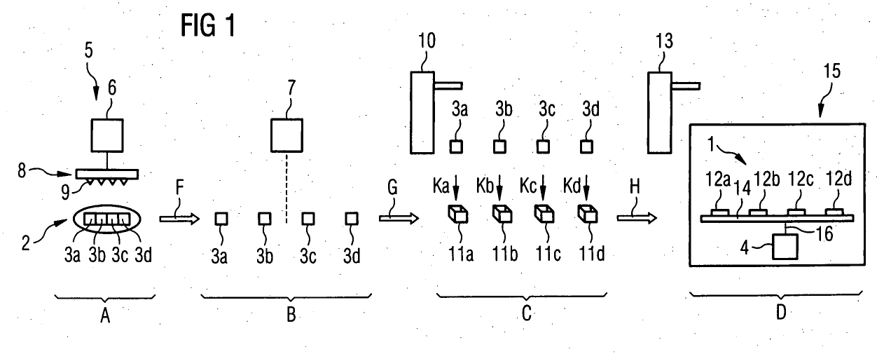

FIG. 1 schematically shows some (out of a plurality of further, not illustrated) stations A, B, C, D passed through by corresponding semiconductor devices 3a, 3b, 3c, 3d during the manufacturing of semiconductor devices 3a, 3b, 3c, 3d.

At station A, semiconductor devices 3a, 3b, 3c, 3d that are still available on a silicon disc or a wafer 2, respectively, are subject to one or a plurality of spectively, are subject to one or a plurality of testing methods by means of a testing system 5.

Before that, the wafer 2 had been subject, at stations not shown here and preceding the stations A, B, C, D illustrated in FIG. 1, to appropriate, conventional coating, exposure, etching, diffusion and implantation process steps.

The semiconductor devices 3a, 3b, 3c, 3d may, for instance, be appropriate, integrated (analog or digital) computing circuits, or semiconductor memory devices such as functional memory devices (PLAs, PALs, etc.) or table memory devices (e.g. ROMs or RAMs), in particular SRAMs and DRAMs (here e.g. DRAMs (Dynamic Random Access Memories or dynamic read-write memories, respectively) with double data rate (DDR-DRAMs=Double Data Rate DRAMs), advantageously High-Speed DDR-DRAMs).

The testing signals required at station A for testing the semiconductor devices 3a, 3b, 3c, 3d on the wafer 2 are generated by a testing apparatus 6 and are, by means of a semiconductor device probe card 8 (more exactly: by means of appropriate contact needles 9 provided on the probe card 8), applied to corresponding pads of the semiconductor devices 3a, 3b, 3c, 3.

When the testing method(s) has (have) been finished successfully, the wafer 2 is transported further (in a fully automated manner) to the following station B (cf. Arrow F) and is there, by means of an appropriate machine 7, sawn apart (or e.g. scratched and broken), so that the individual semiconductor devices 3a, 3b, 3c, 3d are then available.

After sawing apart the wafer 2 at station B, the devices 3a, 3b, 3c, 3d are (again in a fully automated manner, e.g. by means of an appropriate conveying machine) transported further to the following station C (here: a loading station C) (e.g. directly (or individually, respectively), or alternatively e.g. by means of an appropriate tray) (cf. Arrow G).

At the loading station C, the devices 3a, 3b, 3c, 3d are—individually each—loaded in a fully automated manner by means of an appropriate machine 10 (loading machine) into corresponding housings 11a, 11b, 11c, 11d or packages, respectively (cf. Arrows Kₐ, K_{b}, K_{c}, K_{d}), and the housings 11a, 11b, 11c, 11d are then—in a manner known per se—closed, so that corresponding semiconductor device contacts (provided, for instance, at the bottom of the semiconductor devices 3a, 3b, 3c, 3d) contact corresponding housing contacts (provided, for instance, at the top of the respective housings 11a, 11b, 11c, 11d).

As housings 11a, 11b, 11c, 11d, conventional TSOP housings may, for instance, be used, or e.g. conventional FBGA housings, etc.

Next, the housings 11a, 11b, 11c, 11d are—together with the semiconductor devices 3a, 3b, 3c, 3d—(again in a fully automated manner, e.g. by means of an appropriate conveying machine) transported further to a further station D, e.g. a testing station (cf. Arrow H), or successively to a plurality of different further stations, in particular testing stations (not illustrated).

Station D (or one or a plurality of the above-mentioned, not illustrated, further stations) may e.g. be a so-called burn-in station, in particular a burn-in testing station.

At station D, the housings 11a, 11b, 11c, 11d are loaded by means of an appropriate machine (e.g. a further loading machine 13, or the above-mentioned conveying machine) into corresponding sockets or adapters 12a, 12b, 12c, 12d.

When the sockets or adapters 12a, 12b, 12c, 12d are then closed—in a manner known per se—, corresponding further contacts (provided e.g. at the bottom of the housings 11a, 11b, 11c, 11d) contact corresponding socket contacts (provided e.g. at the top of the respective socket or adapter 12a, 12b, 12c, 12d).

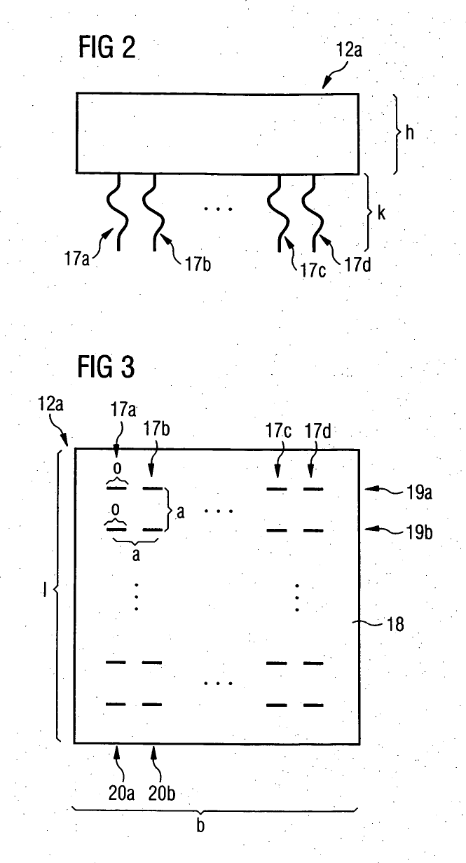

As will be explained more exactly in the following by making reference to FIGS. 2 and 3, a plurality of sockets or adapters 12a, 12b, 12c, 12d (e.g. more than 50, 100, or 200 sockets or adapters 12a, 12b, 12c, 12d) is connected at the station D to one and the same circuit board 14 (or to one and the same test circuit board 14, respectively). The structure of the sockets or adapters 12a, 12b, 12c, 12d may be correspondingly similar to that of conventional burn-in sockets or burn-in adapters (e.g. corresponding TSOP or FBGA burn-in sockets), with the exception of, for instance, the manner—which will be explained in more detail further below—in which the sockets or adapters 12a, 12b, 12c, 12d are connected to the circuit board 14, or—in particular—the exact design of connection pins 17a, 17b, 17c, 17d provided at the sockets 12a, 12b, 12c, 12d.

The test circuit board 14 (and thus also the semiconductor devices 3a, 3b, 3c, 3d or the housings 11a, 11b, 11c, 11d loaded into the sockets or adapters 12a, 12b, 12c, 12d) is—as is also illustrated in FIG. 1—by means of an appropriate machine (e.g. the above-mentioned conveying or loading machine 13, or a further machine) loaded into a “furnace” 15 adapted to be closed (or into a device 15 by which—for the above-mentioned semiconductor devices 3a, 3b, 3c, 3d-extreme conditions can be provided (e.g. high temperature, for instance over 70° C., 100° C., or 150° C., and/or increased device operating voltage, etc.)).

The circuit board 14 (or the test circuit board 14, respectively) can—in a correspondingly conventional manner—be connected to a testing apparatus 4.

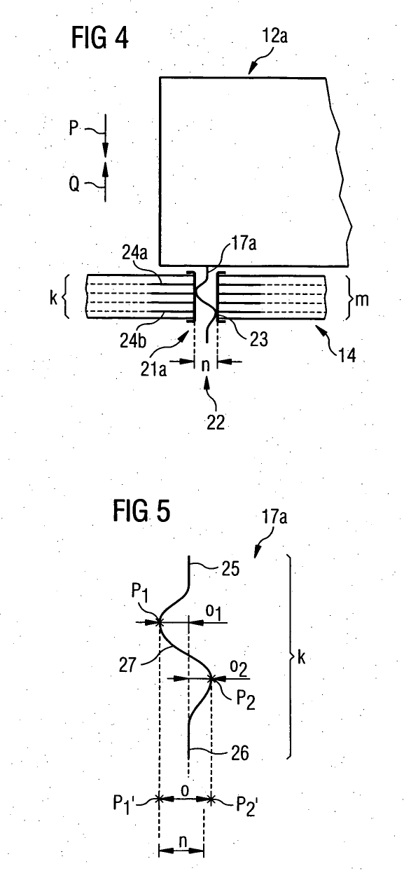

By this, it is achieved that test signals output by the testing apparatus 4 are, e.g. by means of corresponding lines 16, transferred to the test circuit board 14, and from there by means of corresponding circuit board contacts 21a, 21b, 21c, 21d-which are illustrated in detail in FIG. 4—and by connection pins 17a, 17b, 17c, 17d contacting same, to the sockets 12a, 12b, 12c, 12d. From the sockets 12a, 12b, 12c, 12d, the corresponding test signals are then transferred via the above-mentioned socket contacts and the (further) housing contacts contacting same, to the housings 11a, 11b, 11c, 11d, and from there via the above-mentioned housing contacts and the semiconductor device contacts contacting same, to the semiconductor devices 3a, 3b, 3c, 3d to be tested.

The signals output at corresponding semiconductor device contacts in reaction to the test signals input are then correspondingly tapped by corresponding housing contacts (contacting same), and are supplied via the sockets 12a, 12b, 12c, 12d, the circuit board 14, and the lines 16 to the testing apparatus 4, where an evaluation of the corresponding signals can then take place.

Thus, the testing system 1—which i.a. comprises the testing apparatus 4, the circuit board 14, and the sockets 12a, 12b, 12c, 12d—can perform a corresponding, conventional testing method—e.g. a conventional burn-in test (or successively a plurality of such tests), in the course of which the functioning of the semiconductor devices 3a, 3b, 3c, 3d can, for instance, be checked (e.g. while or after the semiconductor devices being subject for a relatively long time (e.g. for more than 30 minutes, or for more than e.g. 1 hour) to the above-mentioned extreme conditions in the above-mentioned “furnace” 15 or the device 15, respectively)).

Since—as explained above—more than 50, 100, or 200 sockets or adapters 12a, 12b, 12c, 12d are connected to the circuit board 14, the testing apparatus 4 illustrated in FIG. 1 can simultaneously test more than 50, 100, or 200 semiconductor devices 3a, 3b, 3c, 3d.

At station D, in particular in the furnace 15, in addition to the above-mentioned (test) circuit board 14, a plurality of further (test) circuit boards being of a structure corresponding to that of the test circuit board (14) and being connected to the testing apparatus 4 (or corresponding further testing apparatuses) may be provided (e.g. more than 20, or more than 30 or 50 (test) circuit boards), to which—in correspondence to the circuit board 14—more than 50, 100, or 200—sockets or adapters having a structure corresponding to that of the sockets or adapters 12a, 12b, 12d, 12e may be connected.

FIG. 2 illustrates a schematic side view of a socket or adapter 12a used with the testing system 1 shown in FIG. 1 (wherein one or a plurality of further, in particular all remaining, sockets or adapters 12b, 12c, 12d that are connected to the circuit board 14 (and possibly to the further circuit boards) may have a structure that is correspondingly identical to that of the socket or adapter 12a illustrated in FIG. 2).

As is illustrated in FIG. 2, the socket or adapter 12a, 12b, 12c, 12d comprises at its bottom 18 a plurality of connection pins 17a, 17b, 17c, 17d (e.g. more than 30, 40, or 60 pins, e.g. substantially corresponding to the number of semiconductor contacts (or housing contacts, respectively) provided or to be tested at the respective semiconductor devices 3a, 3b, 3c, 3d—or at the housings 11a, 11b, 11c, 11d, respectively).

FIG. 3 is a schematic bottom view of the socket 12a, 12b, 12c, 12d illustrated in FIG. 2.

The socket 12a, 12b, 12c, 12d may have a breadth b of e.g. between 10 mm and 4 cm, in particular of e.g. between 20 mm and 2 cm, and a corresponding length l (e.g. also of between 10 mm and 4 cm, in particular of e.g. between 20 mm and 2 cm), and—in accordance with FIG. 2—a height h of e.g. between 5 mm and 3 cm, in particular of between 10 mm and 2 cm.

Preferably, the socket 12a, 12b, 12c, 12d—or more exactly: the socket housing—is made of plastics.

As is illustrated in FIG. 3, the connection pins 17a, 17b, 17c, 17d at the socket bottom 18 are arranged substantially in the form of a plurality of pin rows 19a, 19b (e.g. in the form of more than 4, in particular more than 6 or 8 pin rows), and in the form of a plurality of pin columns 20a, 20b (e.g. in the form of more than 4, in particular more than 6 or 8 pin columns).

The distance a between two adjacent pins 17a, 17b of the same row 19a, 19b (and/or the distance between adjacent pins of the same column 20a, 20b) may be relatively small, e.g. smaller than 1.5 mm or 1 mm, e.g. 0.8 mm or 0.65 mm.

In order to be able to provide on the—relatively small—bottom 18 of the socket 12a, 12b, 12c, 12d the above-mentioned—relatively large—number of connection pins 17a, 17b, 17c, 17d, the connection pins 17a, 17b, 17c, 17d are substantially arranged equidistantly to one another (e.g. with—approximately—the above-mentioned distances a or, alternatively, e.g. also with different distances each for the rows 19a, 19b and the columns 20a, 20b.

The connection pins 17a, 17b, 17c, 17d each are of substantially identical design and each are formed of a resilient or elastic, electrically conductive material, e.g. a corresponding metal alloy, for instance copper-beryllium (CuBe).

The surface of the connection pins 17a, 17b, 17c, 17d may—so as to optimize the respective electrical contact to be produced (in particular with the corresponding circuit board contact 21a, 21b, 21c, 21d)—be provided with a corresponding metal coating, for instance be gold-plated in a conventional manner.

FIG. 4 is a schematic side view of a section of the circuit board 14 illustrated in FIG. 1, and a section of the socket or adapter 12a illustrated in FIGS. 1, 2, and 3.

As results from FIG. 4, the connection pin 17a of the socket or adapter 12a is inserted into the pertinent circuit bar contact 21a provided on the circuit board 14 (and—correspondingly—the remaining connection pins 17b, 17c, 17d of the socket or adapter 12a, and the connection pins of the remaining sockets or adapters 12b, 12c, 12d into the respectively pertinent circuit board contacts 21b, 21c, 21d).

The remaining connection pins 17b, 17c, 17d provided at the socket 12a (and the remaining sockets)—not illustrated in FIG. 4—are of a correspondingly similar or identical structure and design as the connection pin 17a illustrated in FIG. 4.

For providing the circuit board contacts 21a, 21b, 21c, 21d, the circuit board 14 has—in accordance with FIG. 4—during its manufacturing been provided at the corresponding positions with bores 22 passing through the circuit board 14 in transverse direction and having, for instance, substantially circular cross-sections. The bores 22 have relatively small dimensions, e.g. a diameter that may, for instance, be smaller than 0.7 mm, in particular smaller than 0.5 mm, e.g. 0.4 mm.

The inner faces of the bores 22 each are provided with a conductive contact layer, e.g. a metal contact layer 23, the contact layer having a cross-sectional shape corresponding to that of the bores 22, e.g. a substantially circular cross-section.

The inside diameter n of the metal contact layer 23 may e.g. be smaller than 0.6 mm, in particular smaller than 0.4 mm, e.g. 0.3 mm.

As results from FIG. 4, the circuit board 14 is a so-called multilayer circuit board and is manufactured of a non-conductive basic material, e.g. of plastics. The circuit board lines 24a, 24b extend in a plurality of parallel planes and are connected to respectively corresponding circuit board contacts 21a, 21b, 21c, 21d (i.e. are connected with the respectively corresponding metal contact layer 23).

FIG. 5 shows a schematic side view of the connection pins 17a, 17b, 17c, 17d illustrated in FIGS. 2, 3, and 4. They have a length k that may, for instance, be somewhat greater than the thickness m of the circuit board 14 (e.g. a length k of smaller than 2.5 cm, in particular smaller than 2 cm), and they are relatively thin (e.g. with a circular or oval cross-section, having a diameter of e.g. less than 0.1 mm).

The connection pins 17a, 17b, 17c, 17d are fixed to the socket bottom 18 such that, when the respective socket 12a is mounted in the circuit board 14 (i.e. when the socket 12a is shifted downwards in vertical direction, cf. Arrow P in FIG. 4), the respective bottom pin sections 26 of the respective connection pins 17a, 17b, 17c, 17d each are positioned relatively exactly above the (here vertical) central axis of the respectively pertinent bores 22 or circuit board contacts 21a, 21b, 21c, 21d, respectively.

As results from FIG. 5, the top pin section 25 of the respective connection pin 17a, 17b, 17c, 17d extends from the socket bottom 18 in a (first of all) substantially vertical direction to the socket bottom 18.

The bottom pin section 26 of the respective connection pin 17a, 17b, 17c, 17d also extends in a direction extending substantially vertically to the socket bottom 18 (wherein the bottom and the top pin sections 26, 25 may extend in vertical directions substantially lying directly one on top of the other).

The middle pin section 27 positioned between the bottom and the top pin sections 26, 25 has—viewed from the side (cf. FIG. 5)—a curved, in particular a substantially wave-like shape (here: the shape of a complete wave, alternatively e.g. the shape of a double, half, or one and a half wave, etc.).

Particularly advantageously, the middle pin section 27 has the shape of a wave attenuated from the top to the bottom, i.e. a wave having a smaller “amplitude” from the top to the bottom.

The two points P₁, P₂ of the connection pin 17a, 17b, 17c, 17d that are—in horizontal direction—positioned most outside (or more exactly: their projections onto a horizontal plane (points P₁′ und P₂′ in FIG. 2)) have—viewed in horizontal direction—a distance o from one another which is somewhat greater than the inside diameter n of the metal contact layer 23 of the pertinent circuit board contact 21a, 21b, 21c, 21d (e.g. a distance o smaller than 0.7 mm, in particular smaller than 0.5 mm, e.g. 0.4 mm).

Due to the above-explained design of the middle pin section 27 having the shape of a wave attenuated from the top to the bottom, the distance o₁ of the upper point P₁ from the straight line that is e.g. defined by the top or bottom pin section 25, 26 (“zero amplitude”) is greater than the corresponding distance o₂ of the lower point P₂ from the corresponding “middle straight line” or zero amplitude, respectively (wherein the following applies: o₁+o₂=o).

As results e.g. from FIG. 5 (and FIG. 3), the connection pins 17a, 17b, 17c, 17d may, for instance, be designed such that the pin sections 25, 26, 27 are positioned substantially in one and the same vertical plane (the corresponding connection pin 17a, 17b, 17c, 17d may then, for instance, be manufactured by that—starting out from a first of all straight design of the connection pin 17a, 17b, 17c, 17d—the connection pin 17a, 17b, 17c, 17d is bent correspondingly, e.g. by the top portion of the middle pin section 27 first of all being bent over to the left vis-à-vis the top pin section 25, and further below correspondingly to the right (so that the top semi-wave results), and even further below again correspondingly to the left, etc.).

Particularly preferably are the connection pins 17a, 17b, 17c, 17d manufactured—instead of by the above-described bending process—by means of a corresponding punching process (where the connection pins 17a, 17b, 17c, 17d are—in the above-described shape—punched out from a corresponding basic material).

Alternatively, the connection pins 17a, 17b, 17c, 17d may also be manufactured and designed in any other way, e.g. in spiral shape.

When the respective socket 12a is mounted in the circuit board 14 (i.e. when the socket 12a is shifted in vertical direction downwards, cf. Arrow P in FIG. 4), the connection pins 17a, 17b, 17c, 17d are inserted into the respectively pertinent circuit board contacts 21a, 21b, 21c, 21d.

Since, as explained, the connection pins 17a, 17b, 17c, 17d have (viewed in horizontal direction) outer dimensions (distance o between the outer pin points P₁ and P₂ (or their projections P₁′ ad P₂′, respectively)) that are greater than the inner dimensions of the metal contact layers 23 (inside diameter n), the respective connection pin 17a, 17b, 17c, 17d is slightly compressed (in horizontal direction), and a safe electrical contact between the connection pin 17a, 17b, 17c, 17d and the metal contact layer 23 is provided (with at least two contact points, here: the two outer pin points P₁, P₂ (or more exactly: contact points P₁″, P₂′ that are, due to the elastic deformation of the pin, positioned relatively close to these points P₁, P₂).

Therefore, a possible (additional) soldering of the connection pins 17a, 17b, 17c, 17d with the pertinent circuit board contacts 21a, 21b, 21c, 21d is not necessary.

After the insertion of the connection pins 17a, 17b, 17c, 17d, the respective socket 12a may—alternatively—be securely fixed to the circuit board 14 by means of one or a plurality of corresponding screw connections (e.g. by means of one, two, three, or four screws) (and thus e.g. be additionally secured from shifting in vertical direction).

When a faulty socket 12a later is to be removed from the circuit board 14 again and is to be exchanged by a faultless socket, the above-mentioned screw connection (or the above-mentioned screw connections) is/are simply loosened, whereafter the socket 12a can be dismounted from the circuit board 14 (e.g. by shifting the socket 12a in vertical direction upwards, cf. Arrow Q in FIG. 4)—without the circuit board contacts 21a, 21b, 21c, 21d or the connection pins 17a, 17b, 17c, 17d, respectively, having to be unsoldered.

What is claimed is:

1. A socket or adapter device, comprising at least one connection pin, the connection pin configured to be introduced into a corresponding contact device of a device to which the socket or adapter device is to be connected, wherein
the connection pin is configured such that a clamping connection is provided between the contact device and the connection pin when the connection pin is introduced into the contact device.

2. The socket or adapter device according to claim 1, wherein the socket or adapter device is a semiconductor device testing socket or a semiconductor device testing adapter, respectively, which is configured such that, for testing a semiconductor device, it is loaded with a corresponding semiconductor device.

3. The socket or adapter device according to claim 1, wherein the socket or adapter device is a burn-in socket or a burn-in adapter, respectively, which is configured such that, for performing a burn-in test, it is loaded with a corresponding semiconductor device.

4. The socket or adapter device according to claim 1, wherein the connection pin is made of a flexible or resilient material.

5. The socket or adapter device according to claim 4, wherein the metal alloy includes copper and/or beryllium.

6. The socket or adapter device according to claim 1, wherein at least one section of the connection pin has a curved shape.

7. The socket or adapter device according to claim 6, wherein the section of the connection pin has the shape of a wave attenuated in a direction leading away from the socket or adapter device.

8. The socket or adapter device according to claim 1, wherein the device comprising the contact device is a circuit board configured to be connected to a testing apparatus.

9. The socket or adapter device according to claim 1, wherein the device comprising the contact device is a testing apparatus.

10. The socket or adapter device according to claim 1, wherein the contact device comprises a recess or a bore into which the connection pin is introduced.

11. A system, comprising:
at least one socket or adapter device; and
at least one semiconductor device testing apparatus or at least one circuit board, wherein
the socket or adapter device comprises at least one connection pin which is configured to be introduced into a corresponding contact device for connection to the testing apparatus or to the circuit board that can be connected with a testing apparatus,
wherein the connection pin is configured such that a clamping connection is provided between the contact device and the connection pin when the connection pin is introduced into the contact device.

12. The system according to claim 11, wherein the connection between the connection pin and the contact device is performed without soldering.

13. The system according to claim 12, wherein the socket or adapter device comprises a plurality of connection pins that are connected with respectively corresponding contact devices, and wherein the connections between the connection pins and the respectively corresponding contact devices each are performed without soldering.

14. A method for testing semiconductor devices, comprising:
connecting a socket or adapter device to a testing system, wherein at least one connection pin of the socket or adapter device is introduced into a corresponding contact device;
loading the socket or adapter device with a semiconductor device to be tested,
wherein the connection pin is configured such that a clamping connection is provided between the contact device and the connection pin when the connection pin is introduced into the contact device.
